(19) United States
(12) Patent Application Publication
(10) Pub. No.: US 2003/0080832 A1
(43) Pub. Date: May 1, 2003

(54) Single chip scale package

(76) Inventor: Hesham M. Enshasy, Whitehall, PA (US)

Correspondence Address: STEVEN WESEMAN, CTS CORPORATION, 171 COVINGTON DRIVE, BLOOMINGDALE, IL, 60108, US

(21) Appl. No.: 10/152,459

(22) Filed: May 21, 2002

Related U.S. Application Data
(60) Provisional application No. 60/294,344, filed on May 30, 2001.

(51) Int. Cl. H03H 9/00

(52) U.S. Cl. 333/193

(57) ABSTRACT

The present invention provides a surface acoustic wave (SAW) device. The SAW device provides a SAW die made from a piezoelectric material and has an active region. The active region has metallized and interdigitated electrodes attached to it. The interdigitated electrodes are attached to metallized I/O pads on the SAW die. The SAW device also provides a substrate having top substrate pads on a first surface thereof and bottom substrate pads on an opposing surface thereof and vias filled with a conductive material to electrically connect the top substrate pads to the bottom substrate pads. Also provided are means for attaching the SAW die to the substrate, the means having a size and shape such that it surrounds the active region of the SAW die and hermetically seals the active region of the SAW, and means for electrically connecting each top ubstrate pad to a corresponding I/O pad.

### CROSS-REFERENCE TO RELATED APPLICATION

This application claims the benefit of the filing date of U.S. Provisional Patent Application, Ser. No. 60/294,344, filed on May 30, 2001, which is explicitly incorporated by reference.

### FIELD OF THE INVENTION

The field of the invention relates to surface acoustic wave devices and more particularly to chip scale packaging of surface acoustic wave devices.

### BACKGROUND OF THE INVENTION

The pressure in the industry for surface acoustic wave (SAW) devices is to create smaller and cheaper devices without sacrificing device performance. As a result, manufacturers have sought to reduce the number of parts in the packaging of SAW devices in order to reduce product cost, area and height. The packaging of a SAW device, and the processes required to assemble the packaging, can represent as much as 60% of the cost of a SAW device. As a result, eliminating parts and their assembly processes results in large gains in the reduction of the price of a SAW device.

Previously, SAW devices used a substrate having a recessed portion and a lid to cover the recessed portion, with the SAW die placed within the recessed portion. In this manner, the SAW device is hermetically sealed to protect its active portion from contamination from outside elements. However, such configurations have proven large and expensive to produce. Therefore, there is a need within the art for smaller and cheaper SAW devices. The present invention fills that need with an inventive method and apparatus for packaging a SAW device which has fewer parts and costs less to produce.

### SUMMARY OF THE INVENTION

The present invention provides a surface acoustic wave (SAW) device. The SAW device comprises a SAW die made from a piezoelectric material and has an active region. The active region has metallized and interdigitated electrodes attached to it. The interdigitated electrodes are attached to metallized I/O pads on the SAW die. The SAW device also comprises a substrate having top substrate pads on a first surface thereof and bottom substrate pads on an opposing surface thereof and vias filled with a conductive material to electrically connect the top substrate pads to the bottom substrate pads. Also provided are means for attaching the SAW die to the substrate, the means having a size and shape such that it surrounds the active region of the SAW die and hermetically seals the active region of the SAW, and means for electrically connecting each top substrate pad to a corresponding I/O pad.

### BRIEF DESCRIPTION OF THE DRAWINGS

FIG. 1 is a section view of a first step in constructing a SAW device according to the present invention;

FIG. 2 is a plan view of a first step in constructing a SAW device according to the present invention;

FIG. 3 is a section view of a second step in constructing a SAW device according to the present invention;

FIG. 4 is a section view of a third step in constructing a SAW device according to the present invention;

FIG. 5 is a plan view of a third step in constructing a SAW device according to the present invention; and

FIG. 6 is a section view of a SAW device according to the present invention.

### DETAILED DESCRIPTION OF THE PREFERRED EMBODIMENT

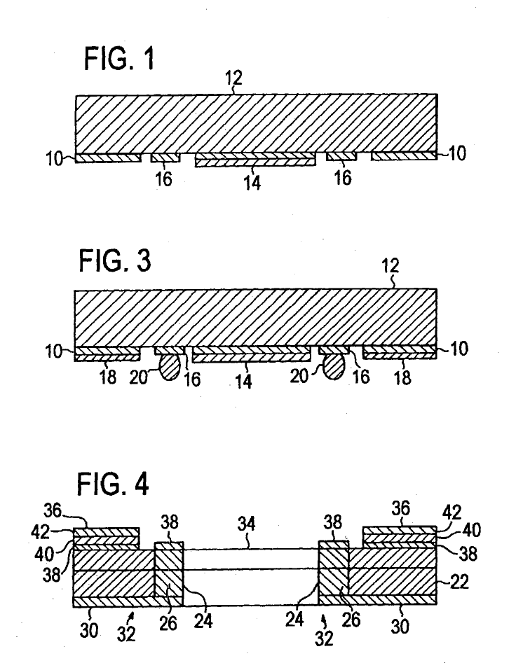

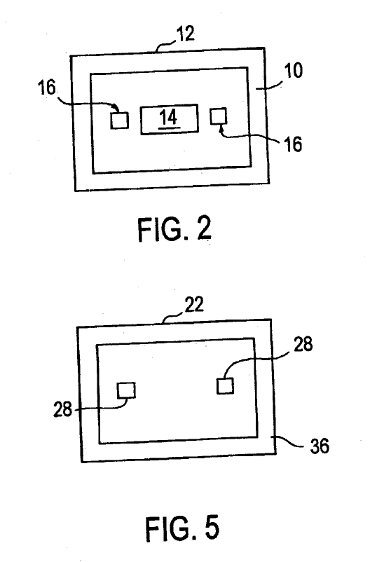

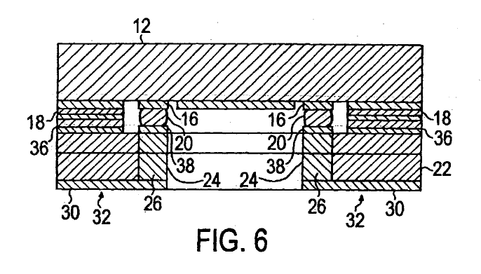

Referring to FIG. 1, the surface acoustic wave device (SAW) of the present invention is constructed applying a SAW die ring 10 on an outer perimeter (dimensions A and B) of a SAW die 12. It should be understood that while the word ring is used to describe the SAW die ring 10, the saw die ring 10 is not limited to any particular shape and may be circular, square, rectangular, form an irregular shape, etc. The SAW die ring 10 surrounds an active region 14 on one side of the SAW die 12. The active region 14 of the SAW die 12 is defined as the area of the die in which electrical signals are converted to acoustic waves and back to electrical signals. The active region 14 comprises interdigitated electrodes 15 that are formed in the active region, preferably from aluminum. The SAW die 12 further comprises an input and an output pad, hereafter referred to collectively as SAW I/O pads 16, which are also located within the SAW die ring 10. The SAW die ring 10 has a width of about 0.3 to 0.8 mm and is about 1000 nm thick.

Referring to FIG. 3, next a layer 18 of gold is deposited on top of the SAW die ring 10 with a thickness of about 150 nm. The layer of gold acts as a solderable layer. Next, conductive bumps 20 are applied to the SAW I/O pads 16. The conductive bumps are preferably made from 38 μm gold wire and have a thickness of about 160 μm.

In FIGS. 4 and 5, there is shown a substrate 22 having the same general outer dimensions A and B as the SAW die 12. The substrate is preferably made from ceramic, although other non-conducting material may be used. The substrate has two vias 24 extending through its thickness. The vias are filled with an electrically conducting material 26, preferably gold, to electrically connect top substrate pads 28 and bottom substrate pads 30 to form two unitary substrate l/O pads 32. A top side 34 of the substrate 22 comprises a substrate ring 36. The substrate ring 36 comprises a bottom layer 38 of nickel of about 50 μm thickness, a middle layer 40 of gold of about 1.02 μm and a top layer 42 of solder of about 14 μm thickness. The substrate ring 36 is of the same general dimensions as the SAW die ring 10.

Finally, the SAW die 12 is preferably attached to the substrate 22 by reflowing the top layer 42 of solder and thermosonically bonding the conductive bumps 20 to the top substrate pads 28; however, appropriate methods of attachment depend on the materials used. In this manner, the active region 14 of the SAW die 12 is hermetically sealed to protect it from airborne contaminants. If a SAW die 12 of about 0.5 mm thickness is used and a substrate of about 0.38 mm is used, the result is a surface mountable SAW device of slightly less than 1 mm thickness.

While the present invention is shown and described using a single SAW die 12 and a single substrate 22, it should be understood that the present invention can be most economically manufactured by forming several SAW dies 12 on a single piece of piezoelectric material and several substrates 22 on a single piece of substrate material and attaching the piezoelectric material and the substrate material and dicing the SAW devices from the larger sheets.

A specific embodiment of a method and apparatus for providing a SAW device according to the present invention has been described for the purpose of illustrating the manner in which the invention is made and used. It should be understood that the implementation of other variations and modifications of the invention and its various aspects will be apparent to one skilled in the art, and that the invention is not limited by the specific embodiments described. Therefore, it is contemplated to cover the present invention and any and all modifications, variations, or equivalents that fall within the true spirit and scope of the basic underlying principles disclosed and claimed herein.

I claim:

1. A surface acoustic wave (SAW) device comprising:
a SAW die made from a piezoelectric material and comprising an active region, the active region comprising metallized interdigitated electrodes attached thereto, the interdigitated electrodes attached to metallized I/O pads on the SAW die;
a SAW die ring attached to the SAW die and surrounding the active area of the piezoelectric substrate;
a substrate comprising top substrate pads on a first surface thereof and bottom substrate pads on an opposing surface thereof and vias filled with a conductive material to electrically connect the top substrate pads to the bottom substrate pads;
a substrate ring attached to the substrate, the substrate ring having a substantially similar shape and size as the SAW die ring; and
wherein the SAW die is attached to the substrate via the SAW die ring and the substrate ring and each top substrate pad is electrically connected to a corresponding I/O pad.

2. The device of claim 1 wherein a face of the substrate and a face of the SAW die comprising the active region have substantially equal outer dimensions.

3. The device of claim 1 wherein the attachment between the SAW die ring and substrate ring forms a hermetic seal.

4. The device of claim 1 wherein each top substrate pad is electrically connected to a corresponding I/O pad by a gold conductive bump.

5. The device of claim 1 wherein the substrate ring comprises a layer of nickel, a layer of gold, and a layer of solder.

6. The device of claim 1 wherein the top substrate pads are plated with gold.

7. The device of claim 1 wherein the SAW die ring comprises a layer of aluminum and a layer of gold.

8. The device of claim 1 wherein the substrate comprises a ceramic material.

9. A surface acoustic wave (SAW) device comprising:
a SAW die made from a piezoelectric material and comprising an active region, the active region comprising metallized and interdigitated electrodes attached thereto, the interdigitated electrodes attached to metallized I/O pads on the SAW die;
a substrate comprising top substrate pads on a first surface thereof and bottom substrate pads on an opposing surface thereof and vias filled with a conductive material to electrically connect the top substrate pads to the bottom substrate pads;
means for attaching the SAW die to the substrate, the means having a size and shape such that it surrounds the active region of the SAW die and hermetically seals the active region of the SAW; and
means for electrically connecting each top substrate pad to a corresponding I/O pad.

10. The device of claim 9 wherein a face of the substrate and a face of the SAW die comprising the active region have substantially equal outer dimensions.

11. The device of claim 9 wherein each top substrate pad is electrically connected to a corresponding I/O pad by a gold conductive bump.

12. The device of claim 9 wherein the substrate ring comprises a layer of nickel, a layer of gold and a layer of solder.

13. The device of claim 9 wherein the top substrate pads are plated with gold.

14. The device of claim 9 wherein the SAW die ring comprises a layer of aluminum and a layer of gold.

15. The device of claim 1 wherein the substrate comprises a ceramic material.
